(19) United States
(12) Patent Application Publication
(10) Pub. No.: US 2026/0043873 A1
(43) Pub. Date: Feb. 12, 2026

(54) SECONDARY BATTERY PENETRATION TEST APPARATUS AND METHOD AND NAIL FOR PENETRATION TEST

(71) Applicant: SAMSUNG SDI CO., LTD., Yongin-si (KR)

(72) Inventor: Minhyung GUEN, Yongin-si (KR)

(21) Appl. No.: 19/069,433

(22) Filed: Mar. 4, 2025

(30) Foreign Application Priority Data
Aug. 7, 2024 (KR) 10-2024-0105741

(51) Int. Cl. G01R 31/52; H01M 10/42

(52) U.S. Cl. CPC G01R 31/52; H01M 10/4285

(57) ABSTRACT

A secondary battery penetration test apparatus, including a nail inserted into an electrode assembly of a secondary battery to cause a short circuit between a negative electrode plate and a positive electrode plate, wherein the nail includes a conductive portion configured to short-circuit an n^{th} negative electrode plate (n is a natural number greater than or equal to 1) and a k^{th} positive electrode plate (k is a natural number greater than or equal to 1) of the electrode assembly, and a non-conductive portion in an area excluding the conductive portion.

### CROSS-REFERENCE TO RELATED APPLICATION

This application claims priority to and the benefit of Korean Patent Application No. 10-2024-0105741, filed on Aug. 7, 2024, the disclosure of which is incorporated herein by reference.

### BACKGROUND

### 1. Field

Embodiments relate to a secondary battery penetration test apparatus and a method and a nail used for a penetration test.

### 2. Description of the Related Art

Unlike primary batteries that cannot be recharged, secondary batteries are batteries that can be charged and discharged. In general, a secondary battery includes an electrode assembly including positive and negative electrode plates, a case accommodating the electrode assembly, electrode terminals connected to the electrode assembly, a vent for discharging gases (degassing) generated inside the case, and the like.

The above information disclosed in this Background section is for enhancement of understanding of the background of the present disclosure, and therefore, it may contain information that does not constitute a related (or prior) art.

### SUMMARY

Embodiments include a secondary battery penetration test apparatus, including a nail inserted into an electrode assembly of a secondary battery to cause a short circuit between a negative electrode plate and a positive electrode plate, wherein the nail includes a conductive portion configured to short-circuit an n^{th} negative electrode plate (n is a natural number greater than or equal to 1) and a k^{th} positive electrode plate (k is a natural number greater than or equal to 1) of the electrode assembly, and a non-conductive portion in an area excluding the conductive portion.

The conductive portion of the nail may be in an area including a tip of the nail.

The conductive portion of the nail may extend from a tip of the nail by a distance between the n^{th} negative electrode plate and the k^{th} positive electrode plate of the electrode assembly.

The conductive portion of the nail may be in an area not including a tip of the nail.

Excluding a tip of the nail, the conductive portion of the nail may be in an area that is outside of a distance between the nth negative electrode plate and the kth positive electrode plate of the electrode assembly.

The non-conductive portion of the nail may be in an area including a tip of the nail.

Excluding a tip of the nail, the non-conductive portion of the nail may be in an area that is outside of a distance between the n^{th} negative electrode plate and the k^{th} positive electrode plate of the electrode assembly.

n may equal k.

n may not equal k.

The nail may include a conductor, and the non-conductive portion of the nail may include an insulating material on a surface of a nail area excluding the conductive portion.

The nail may include a non-conductor, and the conductive portion of the nail may include a conductive material on a surface of a nail area excluding the non-conductive portion.

The conductive portion made of a conductor and the non-conductive portion made of a non-conductor may be joined together.

Embodiments include a secondary battery penetration test method, including inserting a nail including a conductive portion and a non-conductive portion into an electrode assembly of a secondary battery, resulting in an inserted nail, and positioning the nail to be seated at a position at which the conductive portion of the inserted nail short-circuits an n^{th} negative electrode plate (n is a natural number greater than or equal to 1) and a k^{th} positive electrode plate (k is a natural number greater than or equal to 1) of the electrode assembly.

The secondary battery penetration test method may further include charging the secondary battery prior to inserting the nail into the electrode assembly of the secondary battery.

n may equal k.

n may not equal k

Embodiments include a nail for a secondary battery penetration test, the nail including a conductive portion inserted into an electrode assembly to short-circuit an n^{th} negative electrode plate (n is a natural number greater than or equal to 1) and a k^{th} positive electrode plate (k is a natural number greater than or equal to 1) of the electrode assembly, and a non-conductive portion in an area of the nail excluding the conductive portion.

The conductive portion of the nail may extend from a tip of the nail by a distance between the n^{th} negative electrode plate and the k^{th} positive electrode plate of the electrode assembly.

Excluding a tip of the nail, the conductive portion of the nail may be in an area outside of a distance between the n^{th} negative electrode plate and the k^{th} positive electrode plate of the electrode assembly.

Excluding a tip of the nail, the non-conductive portion of the nail may be in an area outside of a distance between the negative electrode plate and the positive electrode plate of the electrode assembly.

Aspects and features of the present disclosure not specifically mentioned herein will be clearly understood by those of ordinary skill in the art from the description of the present disclosure below.

### BRIEF DESCRIPTION OF THE DRAWINGS

Features will become apparent to those of ordinary skill in the art by describing in detail exemplary embodiments with reference to the attached drawings, in which:

FIG. 1 schematically illustrates an electrode assembly of a secondary battery;

FIG. 2 schematically illustrates a pouch-type secondary battery;

FIG. 3 is a cross-sectional view of a cylindrical secondary battery;

FIG. 4 is a view of an internal configuration of a prismatic secondary battery;

FIG. 5 is an example of a penetration test in which a nail is hit and inserted into an electrode assembly of a secondary battery in accordance with one or more embodiments of the present disclosure;

FIGS. 6A and 6B are exemplary views illustrating a short circuit of an electrode plate induced with a nail for an electrode plate short-circuit test which is one of the various purposes of a penetration test, wherein FIG. 6A illustrates a situation in which a single short circuit occurs, and FIG. 6B illustrates a situation in which multiple short circuits occur.

FIG. 7 illustrates a nail according to one or more embodiments of the present disclosure;

FIG. 8 is a schematic view of an electrode plate short-circuit test using the nail of FIG. 7, in accordance with one or more embodiments of the present disclosure;

FIG. 9A illustrates a nail according to one or more other embodiments of the present disclosure;

FIG. 9B is a schematic view of an electrode plate short-circuit test using the nail (410) of FIG. 9A;

FIG. 10A illustrates a nail according to one or more other embodiments of the present disclosure; and

FIG. 10B is a schematic view of an electrode plate short-circuit test using the nail of FIG. 10A.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those of ordinary skill in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

The terms or words used in the present specification and claims are not to be narrowly interpreted according to their general or dictionary meanings and should be interpreted as having meanings and concepts that are consistent with the technical idea of the present disclosure on the basis of the principle that an inventor can be his/her own lexicographer to appropriately define concepts of terms to describe his/her embodiments in the best way.

The embodiments described in this specification and the configurations shown in the drawings are only some embodiments of the present disclosure and do not represent all of the aspects, features, and embodiments of the present disclosure. Accordingly, it should be understood that there may be various equivalents and modifications that can replace or modify one or more embodiments or features therein described herein at the time of filing this application.

It will be understood that if an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, if a first element is described as being “coupled” or “connected” to a second element, the first element may be directly coupled or connected to the second element or the first element may be indirectly coupled or connected to the second element via one or more intervening elements.

As used herein, the term “and/or” includes any and all combinations of one or more of the associated listed items. Further, the use of “may” if describing embodiments of the present disclosure relates to “one or more embodiments of the present disclosure.” Expressions, such as “at least one of” and “any one of,” if preceding a list of elements, modify the entire list of elements and do not modify the individual elements of the list. When phrases such as “at least one of A, B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” if used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all subranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. §132(a).

References to two compared elements, features, etc. as being “the same” may mean that they are “substantially the same.” Thus, the phrase “substantially the same” may include a case having a deviation that is considered low in the art, for example, a deviation of 5% or less. In addition, if a certain parameter is referred to as being uniform in a given region, it may mean that it is uniform in terms of an average.

Throughout the specification, unless otherwise stated, each element may be singular or plural.

Arranging an arbitrary element “above (or below)” or “on (under)” another element may mean that the arbitrary element may contact the upper (or lower) surface of the element, and another element may also be interposed between the element and the arbitrary element located on (or under) the element.

In addition, it will be understood that if a component is referred to as being “linked,” “coupled,” or “connected” to another component, the elements may be directly “coupled,” “linked” or “connected” to each other, or another component may be “interposed” between the components.”

Throughout the specification, if “A and/or B” is stated, it means A, B or A and B, unless otherwise stated. That is, “and/or” includes any or all combinations of a plurality of items enumerated. When “C to D” is stated, it means C or more and D or less, unless otherwise specified.

The terminology used herein is for the purpose of describing embodiments of the present disclosure and is not intended to limit the present disclosure.

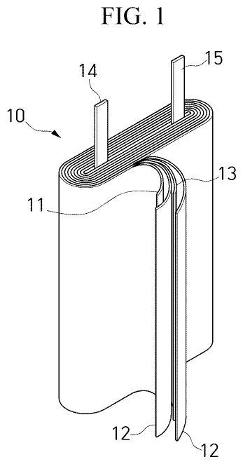

FIG. 1 shows an electrode assembly of a secondary battery.

Referring to FIG. 1, an electrode assembly 10 may be formed by winding or stacking a stack of a first electrode plate 11, a separator 12, and a second electrode plate 13, each of which are formed as thin plates or films. When the electrode assembly 10 is a wound stack, a winding axis may be parallel to the longitudinal direction of a case for the electrode assembly. In other embodiments, the electrode assembly 10 may be a stack type rather than a winding type, and the shape of the electrode assembly 10 may be a Z-stack electrode assembly in which a positive electrode plate and a negative electrode plate are inserted into both sides (e.g., opposite sides) of a separator, which is then bent (or folded) into a Z-stack. In addition, one or more electrode assemblies may be stacked (e.g., arranged) such that long sides of the electrode assemblies are adjacent to each other and accommodated in a case, and the number of electrode assemblies may vary. The first electrode plate 11 of the electrode assembly may act as a negative electrode, and the second electrode plate 13 may act as a positive electrode. Of course, the reverse is also possible.

The first electrode plate 11 may be formed by applying (e.g., coating or depositing) a first electrode active material, such as graphite or carbon, onto a first electrode substrate formed of a metal foil, such as copper, a copper alloy, nickel, or a nickel alloy. The first electrode plate 11 may include a first electrode tab 14 (e.g., a first uncoated portion), which is a region to which the first electrode active material is not applied. The first electrode tab 14 may be connected to an external first terminal. In some embodiments, when the first electrode plate 11 is manufactured, the first electrode tab 14 may be formed by being cut in advance to protrude to (or protrude from) one side of the electrode assembly 10, or the first electrode tab 14 may protrude to one side of the electrode assembly 10 more than (e.g., farther than or beyond) the separator 12 without being separately cut.

The second electrode plate 13 may be formed by applying (e.g., coating or depositing) a second electrode active material, such as a transition metal oxide, onto a second electrode substrate formed of a metal foil, such as aluminum or an aluminum alloy. The second electrode plate 13 may include a second electrode tab 15 (e.g., a second uncoated portion), which is a region to which the second electrode active material is not applied. The second electrode tab 15 may be connected to an external second terminal. In some embodiments, the second electrode tab 15 may be formed by being cut in advance to protrude to the other side (e.g., the opposite side) of the electrode assembly 10 when the second electrode plate 13 is manufactured, or the second electrode plate 13 may protrude to the other side of the electrode assembly more than (e.g., farther than or beyond) the separator 12 without being separately cut.

The separator 12 prevents a short-circuit between the first electrode plate 11 and the second electrode plate 13 while allowing movement of lithium ions therebetween. The separator 12 may be made of, for example, a polyethylene film, a polypropylene film, a polyethylene-polypropylene film, or the like.

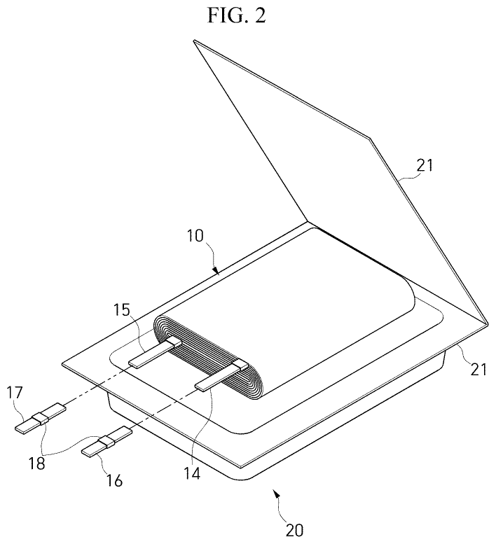

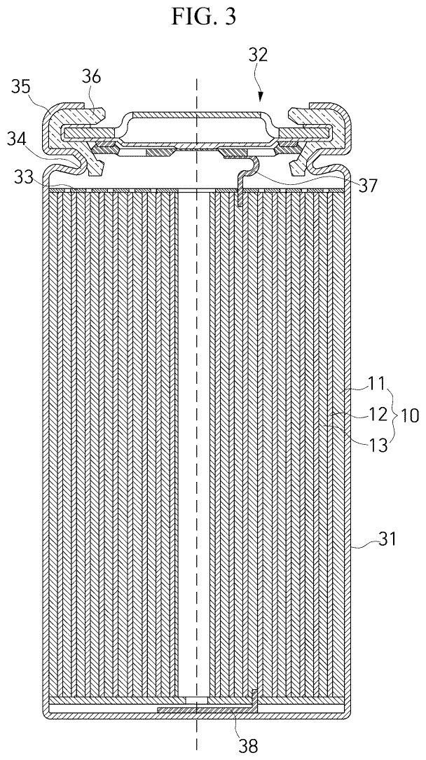

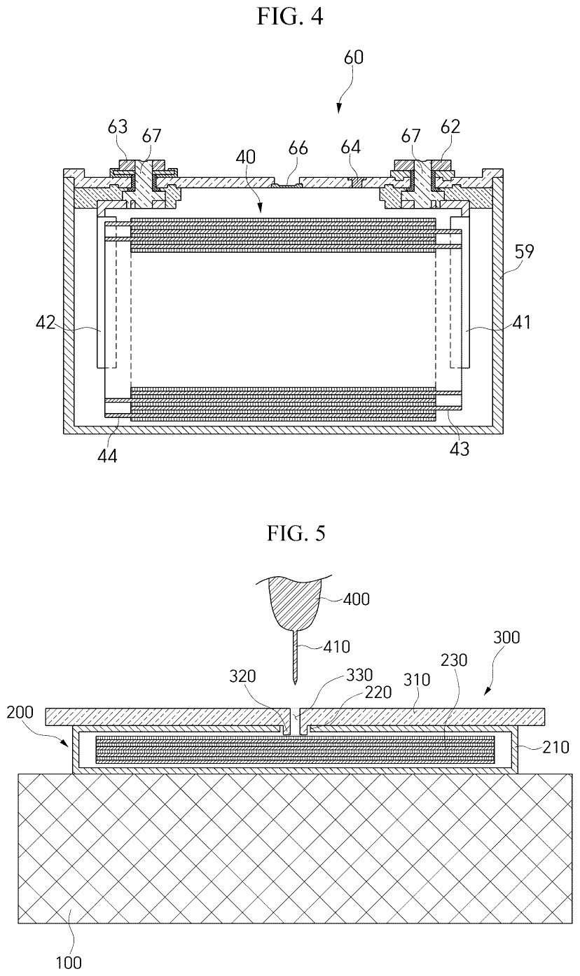

In some embodiments, the electrode assembly 10 may be accommodated in a case along with an electrolyte. In a pouch-type secondary battery, an electrode assembly 10 may be accommodated in a pouch made of flexible material (see, e.g., FIG. 2). In a cylindrical or prismatic secondary battery, an electrode assembly 10 may be accommodated in a cylindrical or prismatic metal casing (see, e.g., FIGS. 3 and 4).

Hereinafter, suitable materials that may be usable for the secondary battery according to one or more embodiments of the present disclosure will be described.

As the positive electrode active material, a compound capable of reversibly intercalating/deintercalating lithium (e.g., a lithiated intercalation compound) may be used. For example, at least one of a composite oxide of lithium and a metal selected from cobalt, manganese, nickel, and combinations thereof may be used.

The composite oxide may be a lithium transition metal composite oxide, and examples thereof may include a lithium nickel-based oxide, a lithium cobalt-based oxide, a lithium manganese-based oxide, a lithium iron phosphate-based compound, a cobalt-free nickel-manganese-based oxide, or a combination thereof.

As an example, a compound represented by any one of the following formulas may be used: LiₐA_{1-b}X_{b}O_{2-c}D_{c} (0.90≤a≤1.8, 0≤b≤0.5, 0≤c≤0.05); LiₐMn_{2-b}X_{b}O_{4-c}D_{c} (0.90≤a≤1.8, 0≤b≤0.5, 0≤c≤0.05); LiₐNi_{1-b-c}Co_{b}X_{c}O_{2-α}D_{α}(0.90≤a≤1.8, 0≤b≤0.5, 0≤c≤0.5, 0<α<2); LiₐNi_{1-b-c}Mn_{b}X_{c}O_{2-α}D_{α}(0.90≤a≤1.8, 0≤b≤0.5, 0≤c≤0.5, 0<α<2); LiₐNi_{1-b-c}Mn_{b}X_{c}O_{2-α}D_{α}(0.90≤a≤1.8, 0≤b≤0.5, 0≤c≤0.5, 0<α<2); LiₐNi_{b}Co_{c}L¹_{d}GₑO₂ (0.90≤a≤1.8, 0≤b≤0.9, 0≤c≤0.5, 0≤d≤0.5, 0≤e≤0.1); LiₐNiG_{b}O₂ (0.90≤a≤1.8, 0.001≤b≤0.1); LiₐCoG_{b}O₂ (0.90≤a≤1.8, 0.001≤b≤0.1); LiₐMn_{1-b}G_{b}O₂ (0.90≤a≤1.8, 0.001≤b≤0.1); LiₐMn₂G_{b}O₄ (0.90≤a≤1.8, 0.001≤b≤0.1); LiₐMn_{1-g}G_{g}PO₄ (0.90≤a≤1.8, 0≤g≤0.5); Li_{(3-f)}Fe₂(PO₄)₃ (0≤f≤2); and LiₐFePO₄ (0.90≤a≤1.8).

In the above formulas: A is Ni, Co, Mn, or a combination thereof; X is Al, Ni, Co, Mn, Cr, Fe, Mg, Sr, V, a rare earth element, or a combination thereof; D is O, F, S, P, or a combination thereof; G is Al, Cr, Mn, Fe, Mg, La, Ce, Sr, V, or a combination thereof; and L¹ is Mn, Al, or a combination thereof.

A positive electrode for a lithium secondary battery may include a substrate and a positive electrode active material layer formed on the substrate. The positive electrode active material layer may include a positive electrode active material and may further include a binder and/or a conductive material.

The content of the positive electrode active material is in a range of about 90 wt% to about 99.5 wt% on the basis of 100 wt% of the positive electrode active material layer, and the content of the binder and the conductive material is in a range of about 0.5 wt% to about 5 wt%, respectively, on the basis of 100 wt% of the positive electrode active material layer.

The substrate may be aluminum (Al) but other materials are possible.

The negative electrode active material may include a material capable of reversibly intercalating/deintercalating lithium ions, lithium metal, an alloy of lithium metal, a material capable of being doped and undoped with lithium, or a transition metal oxide.

The material capable of reversibly intercalating/deintercalating lithium ions may be a carbon-based negative electrode active material, which may include, for example, crystalline carbon, amorphous carbon, or a combination thereof. Examples of the crystalline carbon may include graphite, such as natural graphite or artificial graphite, and examples of the amorphous carbon may include soft carbon, hard carbon, a pitch carbide, a meso-phase pitch carbide, sintered coke, and the like.

A Si-based negative electrode active material or a Sn-based negative electrode active material may be used as the material capable of being doped and undoped with lithium. The Si-based negative electrode active material may be silicon, a silicon-carbon composite, SiOₓ (0<x<2), a Si-based alloy, or a combination thereof.

The silicon-carbon composite may be a composite of silicon and amorphous carbon.

According to one embodiment, the silicon-carbon composite may be in the form of a silicon particle and amorphous carbon coated on the surface of the silicon particle.

The silicon-carbon composite may further include crystalline carbon. For example, the silicon-carbon composite may include a core including crystalline carbon and silicon particle and an amorphous carbon coating layer on the surface of the core.

A negative electrode for a lithium secondary battery may include a substrate and a negative electrode active material layer disposed on the substrate. The negative electrode active material layer may include a negative electrode active material and may further include a binder and/or a conductive material.

For example, the negative electrode active material layer may include about 90 wt % to about 99 wt % of a negative electrode active material, about 0.5 wt % to about 5 wt % of a binder, and about 0 wt % to about 5 wt % of a conductive material.

A non-aqueous binder, an aqueous binder, a dry binder, or a combination thereof may be used as the binder. When an aqueous binder is used as the negative electrode binder, a cellulose-based compound capable of imparting viscosity may be further included.

As the negative electrode substrate, one selected from copper foil, nickel foil, stainless steel foil, titanium foil, nickel foam, copper foam, conductive metal-coated polymer substrate, and combinations thereof may be used.

An electrolyte for a lithium secondary battery may include a non-aqueous organic solvent and a lithium salt.

The non-aqueous organic solvent acts as a medium through which ions involved in the electrochemical reaction of the battery can move.

The non-aqueous organic solvent may be a carbonate-based, an ester-based, an ether-based, a ketone-based, an alcohol-based solvent, an aprotic solvent, and may be used alone or in combination of two or more.

In addition, when a carbonate-based solvent is used, a mixture of cyclic carbonate and chain carbonate may be used.

Depending on the type of lithium secondary battery, a separator may be present between the first electrode plate (e.g., the negative electrode) and the second electrode plate (e.g., the positive electrode). As the separator, polyethylene, polypropylene, polyvinylidene fluoride, or a multilayer film including two or more layers thereof may be used.

The separator may include a porous substrate and a coating layer including an organic material, an inorganic material, or a combination thereof on one or both surfaces of the porous substrate.

The organic material may include a polyvinylidene fluoride-based polymer or a (meth)acrylic polymer.

The inorganic material may include inorganic particles selected from Al₂O₃, SiO₂, TiO₂, SnO₂, CeO₂, MgO, NiO, CaO, GaO, ZnO, ZrO₂, Y₂O₃, SrTiO₃, BaTiO₃, Mg(OH)₂, boehmite, and combinations thereof but other inorganic particles may be used.

The organic material and the inorganic material may be mixed in one coating layer or may be in the form of a coating layer including (or containing) an organic material and a coating layer including (or containing) an inorganic material that are stacked on each other.

FIG. 2 schematically illustrates a pouch-type secondary battery for the electrode assembly 10 of FIG. 1.

The pouch-type secondary battery includes an electrode assembly 10 and a pouch 20 that accommodates the electrode assembly 10.

The electrode assembly 10 is the same as that illustrated in FIG. 1. The first electrode tab 14 and the second electrode tab 15 of the electrode assembly 10 may be electrically connected to respective external first and second terminal leads 16 and 17 by welding.

Each of the first terminal lead 16 and the second terminal lead 17 may be attached with a tab film 18 for insulation from the pouch 20.

The pouch 20 may be sealed by having sealing parts 21 at the edges thereof come into contact with each other with accommodating the electrode assembly 10 therein, in which case the sealing may be achieved with the tab film 18 interposed between the sealing parts 21. The sealing parts 21 of the pouch 20 may each be made of a thermal fusion material that generally has weak adhesion to metal. Thus, it may be fused to the pouch 20 by interposing the thin tab film 18 between the sealing parts 21.

FIG. 3 illustrates a cylindrical secondary battery. As shown in FIG. 3, a secondary battery may include an electrode assembly 10, a case 31 accommodating the electrode assembly 10 and an electrolyte therein, a cap assembly 32 coupled to an opening of the case 31 to seal the case 31, and an insulating plate 33 positioned between the electrode assembly 10 and the cap assembly 32 inside the case 31.

The case 31 accommodates the electrode assembly 10 and the electrolyte, and, together with the cap assembly 32, forms the external appearance of the secondary battery. The case 31 may have a substantially cylindrical body portion and a bottom portion connected to one side (e.g., to one end) of the body portion. A beading part 34 (e.g., a bead) deformed inwardly may be formed in the body portion, and a crimping part 35 (e.g., a crimp) bent inwardly may be formed at an open end of the body portion.

The beading part 34 can reduce or prevent movement of the electrode assembly 10 inside the case 31 and can facilitate seating of the gasket 36 and the cap assembly 32.

The crimping part 35 may firmly fix the cap assembly 32 by pressing the edge of the case 31 against the gasket 36. The case 31 may be formed of iron plated with nickel, for example.

The cap assembly 32 may be fixed to the inside of the crimping part 35 by a gasket 36 to seal the case 31. A first lead tab 37 drawn out from the electrode assembly 10 may be connected to the cap assembly 32, and a second lead tab 38 drawn out from the electrode assembly 10 may be electrically connected to the bottom of the case 31.

With reference to FIG. 4, the internal structure of the prismatic secondary battery and the coupling structure with the cap assembly 60 will be further described.

As shown in FIG. 4, a prismatic secondary battery may include an electrode assembly 40, a first current collector 41, a first terminal 62, a second current collector 42, a second terminal 63, a case 59, and a cap assembly 60.

An electrode assembly 40 may be formed by winding or stacking a stack of a first electrode plate, a separator, and a second electrode plate, which are formed as thin plates or films. When the electrode assembly 40 is a wound stack, a winding axis may be parallel to the longitudinal direction (in the orientation shown) of the case 59. In some other embodiments, the electrode assembly 40 is a stack type rather than a winding type, but other shapes of the electrode assembly 40 are possible. In addition, the electrode assembly 40 may be a Z-stack electrode assembly in which a positive electrode plate and a negative electrode plate are inserted into both sides of a separator, which is then bent into a Z-stack. In addition, one or more electrode assemblies may be stacked such that long sides of the electrode assemblies are adjacent to each other and accommodated in the case, and the number of electrode assemblies in the case may vary. The first electrode plate of the electrode assembly may act as a negative electrode, and the second electrode plate may act as a positive electrode. Of course, the reverse is also possible.

The first electrode plate may be formed by applying a first electrode active material, such as graphite, carbon, or the like, to a first electrode current collector formed of a metal foil, such as copper, a copper alloy, nickel, a nickel alloy, or the like. The first electrode plate may include a first electrode tab 43 (e.g., a first uncoated portion) that is a region to which the first electrode active material is not applied. The first electrode tab 43 may act as a current flow path between the first electrode plate and the first current collector 41. In some embodiments, when the first electrode plate is manufactured, the first electrode tab 43 is formed by being cut in advance to protrude to one side of the electrode assembly 40, or the first electrode tab 43 protrudes to one side of the electrode assembly 40 more than (e.g., farther than or beyond) the separator without being separately cut.

The second electrode plate may be formed by applying a second electrode active material, such as a transition metal oxide, on a second electrode current collector formed of a metal foil, such as aluminum or an aluminum alloy. The second electrode plate may include a second electrode tab 44 (e.g., a second uncoated portion) that is a region to which the second electrode active material is not applied. The second electrode tab 44 may act as a current flow path between the second electrode plate and the second current collector 42. In some embodiments, the second electrode tab 44 may be formed by being cut in advance to protrude to the other side (e.g., the opposite side) of the electrode assembly when the second electrode plate is manufactured, or the second electrode plate may protrude to the other side of the electrode assembly more than (e.g., farther than or beyond) the separator without being separately cut.

The separator prevents or substantially reduces instances of a short circuit between the first electrode and the second electrode while allowing movement of lithium ions therebetween. The separator may be made of, for example, a polyethylene film, a polypropylene film, a polyethylene-polypropylene film, or the like.

In some embodiments, the electrode assembly 40 is accommodated in the case 59 along with an electrolyte.

In the electrode assembly 40, the first current collector 41 and the second current collector 42 may be welded and connected to the first electrode tab 43 extending from the first electrode plate and the second electrode tab 44 extending from the second electrode plate, respectively. As mentioned above, in some embodiments in which the first electrode tab 43 and the second electrode tab 44 are located at the top of the electrode assembly 40, the first and second current collectors are located at the top of the electrode assembly 40.

As illustrated in FIG. 2, the first current collector 41 and the second current collector 42 are connected to the first terminal 62 and the second terminal 63 through connection members 67, respectively. In some embodiments, the connection members 67 may each have an outer peripheral surface that is threaded, and may be fastened to the first terminal 62 and the second terminal 63 by screwing. However, the connection members 67 may also be coupled to the first terminal 62 and the second terminal 63 by riveting or welding.

FIG. 5 is an example of a penetration test in which a nail is hit and inserted into an electrode assembly of a secondary battery.

A secondary battery penetration test apparatus may mainly include a test stand 100 on which a secondary battery 200 is placed, a partition jig 300 which is installed on a secondary battery 200, of which an electrode plate 230 is exposed through a perforation 220 formed in a case 210 of the secondary battery, to support the secondary battery, a nail 410 which hits the exposed electrode plate 230 of the secondary battery 200 through a hole 330 formed in the partition jig 300, and a chuck 400 which fixes the nail.

For a penetration test, the secondary battery 200 may be placed on the test stand 100, the perforation 220 with a diameter of about 10 mm to about 20 mm may be formed in the case 210 to expose the electrode plate 230 of the electrode assembly, and the secondary battery 200 may be charged. Here, the perforation 220 may be formed using a laser cutter or a physical cutter, but other ways of forming the perforation 220 are possible. In addition, the perforation 220 may be formed in a circular shape, but other shapes are possible.

The partition jig 300 is installed on the secondary battery 200, of which the electrode plate 230 is exposed through the perforation 220, to support and charge the secondary battery, and then a penetration test is performed. After the partition jig 300 is installed, the secondary battery 200 may be charged, or after the secondary battery 200 is charged first, the partition jig 300 may be installed.

A secondary battery charge amount during a short-circuit test may be full charge (100% charge) or partial charge according to the short-circuit test specification. In addition, a temperature sensor, a current/voltage measuring element, or the like may be used to measure temperature or electrical characteristic changes when the nail is hit.

In FIG. 5, more specific elements of a short-circuit test apparatus, such as a lifting mechanism for the nail chuck 400, a mounting mechanism for the secondary battery 200 on the test stand 100, and a fastening structure of the test stand 100 and the partition jig 300, are omitted.

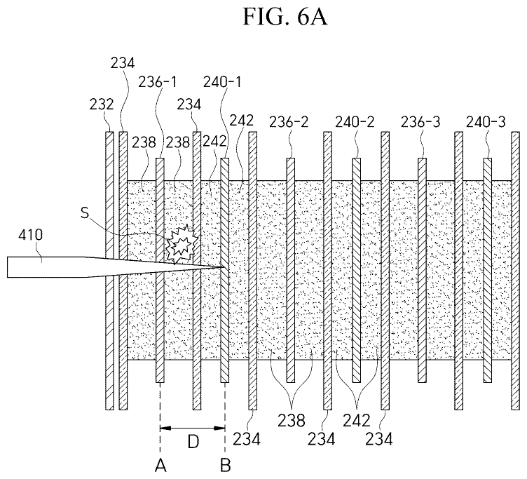

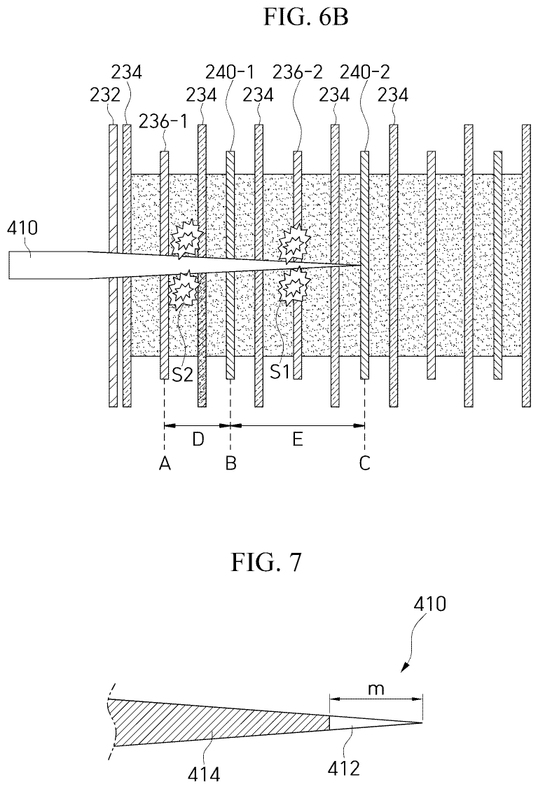

FIGS. 6A and 6B are exemplary views illustrating a process of inducing a short circuit in an electrode plate using a nail 410 for an electrode plate short-circuit test which is one of the purposes of a penetration test. FIG. 6A illustrates a situation in which a single short circuit occurs, and FIG. 6B illustrates a situation in which multiple short circuits occur.

An electrode assembly may have a configuration in which electrode plates are stacked from the left (in the orientation shown) in the order of an insulating tape 232, a separator 234, a first negative electrode plate 236-1, a separator 234, a first positive electrode plate 240-1, a separator 234, a second negative electrode plate 236-2, a second positive electrode plate 240-2, a separator 234, a third negative electrode plate 236-3, a separator 234, and a third positive electrode plate 240-3. Each negative electrode plate 236 is coated with a negative electrode material layer 238, and each positive electrode plate 240 is coated with a positive electrode material layer 242.

The nail 410 is inserted at a specific point of the electrode assembly having such a configuration to induce a short circuit between the electrode plates. Inserting the nail 410 at the specific point of the electrode assembly means simulating a situation in which a conductive foreign material penetrates into or is embedded in a specific electrode plate of the electrode assembly. In this sense, a short-circuit test may be a test in which a foreign material, that is, the nail 410, is seated on a specific electrode plate to induce a short circuit in the corresponding electrode plate to observe a pattern thereof. Through the short-circuit test of the electrode plate, parameters such as the intensity or pattern of explosion or ignition of a battery, a short-circuit current, and a battery voltage may be observed according to a hitting force (impact amount) of an insertion speed, and a penetration distance of the nail 410.

In the short-circuit test shown in FIG. 6A, a tip of the nail 410 passes through the first negative electrode plate 236-1 to penetrate into the first positive electrode plate 240-1. Since the nail 410 is made of a metal and is conductive, the first negative electrode plate 236-1 and the first positive electrode plate 240-1 may mutually undergo a short circuit S in the situation of FIG. 6A, and a short-circuited portion may be a section D between a point A and a point B.

FIG. 6B illustrates a situation in which multiple short circuits occur during an electrode plate short-circuit test and illustrates a situation in which the tip of the nail 410 penetrates into the second positive electrode plate 240-2 to observe a short circuit in a section between the second negative electrode plate 236-2 and the second positive electrode plate 240-2. In the case of such a test, the original intention is to observe a short circuit phenomenon occurring in a section between the second negative electrode plate 236-2 and the second positive electrode plate 240-2, but due to the conductivity of the metallic nail 410, multiple short circuits S1 and S2 occur in unintended sections, which are sections among the first positive electrode plate 240-1, the second negative electrode plate 236-2, and the second positive electrode plate 240-2, that is, not only in a section E between a point B and a point C, but also in a section D between the first negative electrode plate 236-1 and the first positive electrode plate 240-2. Therefore, the purpose of simulating a short circuit in a designed section cannot be achieved. In most penetration tests, ignition or explosion occur in the case of multiple short circuits.

A secondary battery penetration test apparatus of the present disclosure designed to solve the above-described problem will be described.

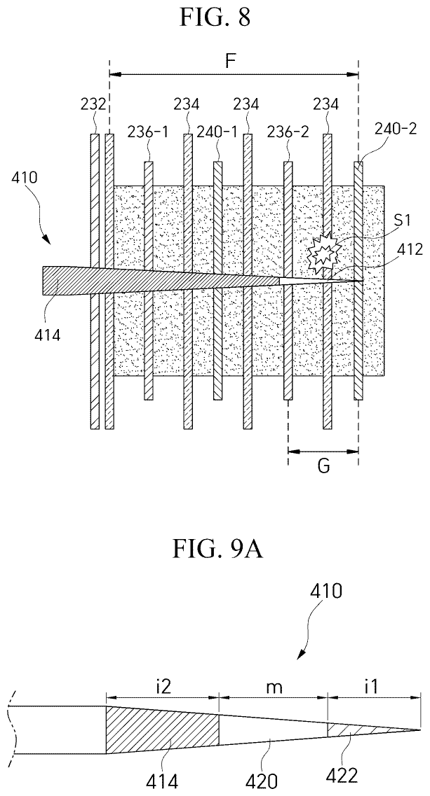

FIG. 7 illustrates a nail 410 according to one or more embodiments of the present disclosure. FIG. 8 is a schematic view of an electrode plate short-circuit test using the nail 410 of FIG. 7.

The nail 410 shown in FIG. 7 may include a conductive portion 412 for short-circuiting an n^{th} negative electrode plate (n is a natural number greater than or equal to 1) and a k^{th} positive electrode plate (k is a natural number greater than or equal to 1) from an outermost portion of an electrode assembly, and a non-conductive portion 414 positioned in an area excluding the conductive portion 412.

A penetration test may be performed as shown in FIG. 8 using the nail 410 of FIG. 7. In FIG. 8, a tip of the nail 410 penetrates into a second positive electrode plate 240-2. In this case, the conductive portion 412 may be placed in a section G between the second positive electrode plate 240-2 and a second negative electrode plate 236-1 so that a short circuit may occur between the second positive electrode plate 240-2 and the second negative electrode plate 236-2. In other sections, a short circuit cannot occur due to the non-conductive portion 414 of the nail 410. Therefore, a short circuit may occur only in the section G within an insertion distance F of the nail 410, that is, in a section in which the conductive portion 412 is positioned. When a short circuit is intended in the section G, an intended short-circuit induction point may be accurately simulated.

In some embodiments, the conductive portion 412 of the nail 410 may be positioned in an area including the tip of the nail 410 as shown in FIG. 7.

In some embodiments, the conductive portion 412 of the nail 410 may extend from the tip of the nail to a distance that includes a distance between a negative electrode plate and a positive electrode plate of the electrode assembly. For example, the distance between the negative electrode plate and the positive electrode plate may be included in an area of an extension distance m of the conductive portion 412 shown in FIG. 7.

In one or more embodiments, excluding the tip of the nail, the non-conductive portion 414 of the nail 410 may be positioned in an area that is outside of the distance between the negative electrode plate and the positive electrode plate of the electrode assembly. For example, as shown in FIG. 7, the conductive portion 412 may extend from the tip of the nail tip by the distance m including the distance between the negative electrode plate and the positive electrode plate of the electrode assembly, and the non-conductive portion 414 may be positioned in the remaining section.

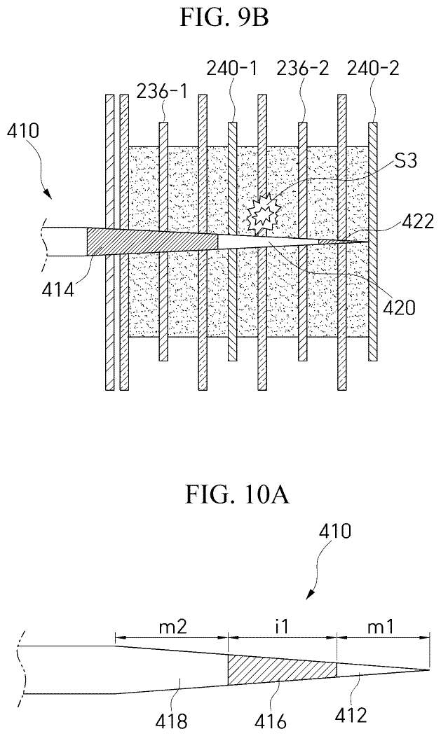

FIG. 9A illustrates a nail 410 according to one or more embodiments of the present disclosure. FIG. 9B is a schematic view of an electrode plate short-circuit test using the nail 410 of FIG. 9A.

As shown in FIG. 9A, a first non-conductive portion 422 is positioned in an area including a tip of the nail, and a conductive portion 420 is positioned in an area not including the tip of the nail. For example, the first non-conductive portion 422 may extend from the tip of the nail by a distance i1, and the conductive portion 412 may extend by a distance m after the distance i1.

In some embodiments, excluding the tip of the nail, the conductive portion 420 of the nail 410 may be positioned in an area that is outside of a distance between a negative electrode plate and a positive electrode plate of an electrode assembly. For example, as shown in FIG. 9B, although the tip of the nail penetrates into a second positive electrode plate 240-2, since the first non-conductive portion 422 is positioned at the tip, the second positive electrode plate 240-2 is excluded from an electrode plate to be short-circuited, and a first positive electrode plate 240-1 and a second negative electrode plate 236-2 may be positioned in an area of the conductive portion 420 positioned at a middle portion of the nail so that these plates may mutually undergo a short circuit S3 by the conductive portion 420.

In some embodiments, the nail 410 may include a second non-conductive portion 414 positioned at a side of the nail 410 opposite to the first non-conductive portion 422 with which the conductive portion 420 is in contact. An extension distance i2 of the second non-conductive portion 414 may be a distance that is beyond an outermost electrode plate (first negative electrode plate 236-1 in FIG. 9B) of the electrode assembly from a position adjacent to the conductive portion 420. For example, the second non-conductive portion 414 may prevent a short circuit between the first negative electrode plate 236-1 and the first positive electrode plate 240-1 in the situation shown in FIG. 9B.

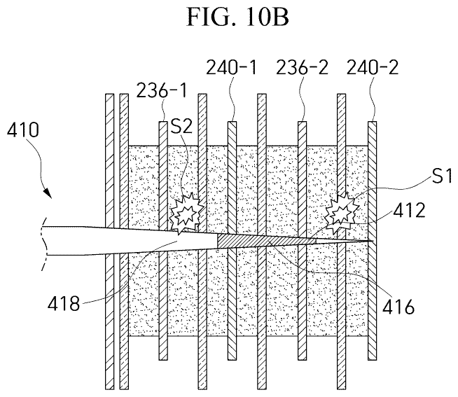

FIG. 10A illustrates a nail 410 according to one or more other embodiments of the present disclosure. FIG. 10B is a schematic view of an electrode plate short-circuit test using the nail 410 of FIG. 10A.

In the embodiment shown in FIG. 10A, a first conductive portion 412 is positioned in an area including a tip of the nail as in the case of FIG. 7, and a non-conductive portion 416 is positioned subsequent to the first conductive portion 412. A second conductive portion 418 is positioned subsequent to the non-conductive portion 416. In other words, the non-conductive portion 416 is between the first conductive portion 412 and the second conductive portion 418.

An extension distance m1 of the first conductive portion 412 is sufficient as long as the first conductive portion 412 penetrates into and comes into contact with one of a positive electrode plate and a negative electrode plate. For example, in FIG. 10B, the conductive portion 412 penetrates into and comes into contact with a second positive electrode plate 240-2 and does not come into contact with other negative electrode plates.

Excluding the tip of the nail, an extension distance i1 of the non-conductive portion 416 may be positioned in an area that is outside of a distance between the negative electrode plate and the positive electrode plate of an electrode assembly. For example, in FIG. 10B, a second negative electrode plate 236-2 and a first positive electrode plate 240-1 are positioned in an area of the non-conductive portion 416.

A penetration test using the nail 410 shown in FIG. 10A may be performed as shown in FIG. 10B. The first conductive portion 412 is in contact with the second positive electrode plate 240-2, and the non-conductive portion 414 electrically insulates the second negative electrode plate 236-2 and the first positive electrode plate 240-1 from a nail surface. Accordingly, the first conductive portion 412 and the second conductive portion 418 are electrically connected, and short circuits S2 and S1 occur in the first negative electrode plate 236-1 and the second positive electrode plate 240-2. That is, a short circuit occurs between electrode plates with different polarities disposed in different groups rather than between electrode plates disposed in the same group.

Therefore, in this example, a short circuit is induced between an n^{th} negative electrode plate and a k^{th} positive electrode plate (k≠n). (On the other hand, in the embodiment of FIG. 9A, a short circuit is induced between electrodes plates of the same group (that is, n=k).) The situation in FIG. 10B assumes that the nail 410 is an integrally connected conductor.

An extension distance m2 of the second conductive portion 418 at a side opposite to the first conductive portion 412 with which the non-conductive portion 416 is in contact may be determined by an intention of a test designer to short-circuit certain electrode plates by electrically connecting the electrode plates to the tip of the nail.

A manufacturing method of nails 410 will be described.

In some embodiments, the nails 410 may be made of a conductor, and non-conductive portions 414, 422, and 416 of the nails 410 may be formed by applying an insulating material on a surface of an area excluding conductive portions 412, 420, and 418 through a method including anodizing or painting.

In some other embodiments, the nails 410 may be made of a non-conductor, and the conductive portions 412, 420, and 418 of the nails 410 may be formed by applying a conductive material on a surface of an area excluding the non-conductive portions 414, 422, and 416 through plating or painting.

In some other embodiments, the nails 410 may be manufactured by joining the conductive portions 412, 420, and 418 made of a conductor and the non-conductive portions 414, 422, and 416 made of a non-conductor.

A penetration test method performed using the above-described nail and a secondary battery penetration test apparatus including the nail will be described. A description of the penetration test method was included in the description of the test apparatus described above and will be briefly summarized below to help understanding.

The penetration test method according to some embodiments of the present disclosure may include inserting a nail including a conductive portion and a non-conductive portion into an electrode assembly of a secondary battery, and positioning the nail to be seated at a position at which the conductive portion of the inserted nail short-circuits an n^{th} positive electrode plate (n is a natural number greater than or equal to 1) and a k^{th} negative electrode plate (k is a natural number greater than or equal to 1) from an outermost portion of the electrode assembly. Here, a relationship between n and k may satisfy n=k as described above. Alternatively, in other embodiments, the relationship between n and k may satisfy n≠k as described above.

In some embodiments, the penetration test method may additionally include, prior to the inserting of the nail including the conductive portion and the non-conductive portion into the electrode assembly of the secondary battery, charging the secondary battery.

In secondary batteries, in particular, there is a high demand for safety. For example, in the case of electric vehicles, an accident may occur due to a short circuit by a negative electrode plate and a positive electrode plate of an electrode assembly coming into contact with each other due to external objects penetrating into an internal electrode assembly or due to foreign materials present inside a cell during manufacturing of the cell. In this case, a very high short-circuit current may flow, which may cause overheating, thermal runaway, or explosion of a battery.

In response to such a demand for safety of secondary batteries, penetration tests are conducted as simulation tests in which, in order to evaluate safety, a nail is caused to penetrate into a secondary battery cell to observe a pattern in which positive and negative electrode plates are short-circuited to each other. When such a short-circuit test is performed, after a secondary battery is charged, a nail is inserted into electrode plates of an electrode assembly to penetrate into a specific electrode plate, thereby inducing a short circuit between a positive electrode plate and a negative electrode plate.

In a nail for a secondary battery short-circuit test and a secondary battery short-circuit test apparatus and method using the same according to the present disclosure, during a secondary battery short-circuit test, a short circuit in an undesired area of an electrode assembly can be prevented to satisfy a test specification. The ultimate purpose of penetration safety evaluation is to design the durability of an electrode assembly against internal foreign materials, and according to the present disclosure, a penetration test or a short-circuit test that meets customer or design requirements becomes possible.

When a short-circuit test of a secondary battery is performed, it is necessary to check a pattern of the occurrence of a short circuit in a specific electrode plate in an electrode assembly according to the request of customers requesting a test or according to the test standards or design specifications.

Therefore, the present disclosure is directed to proposing a secondary battery penetration test using a nail to simulate a foreign material actually being seated at a position of a corresponding electrode plate such that a short circuit occurs only in an intended electrode plate during a secondary battery short-circuit test process.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated.

Accordingly, it will be understood by those of skill in the art that various changes in form and details may be made without departing from the spirit and scope of the present invention as set forth in the following claims.

What is claimed is:

1. A secondary battery penetration test apparatus, comprising:
a nail inserted into an electrode assembly of a secondary battery to cause a short circuit between a negative electrode plate and a positive electrode plate, wherein the nail comprises:
a conductive portion configured to short-circuit an n^{th} negative electrode plate (n is a natural number greater than or equal to 1) and a k^{th} positive electrode plate (k is a natural number greater than or equal to 1) of the electrode assembly; and
a non-conductive portion in an area excluding the conductive portion.

2. The secondary battery penetration test apparatus as claimed in claim 1, wherein the conductive portion of the nail is in an area comprising a tip of the nail.

3. The secondary battery penetration test apparatus as claimed in claim 1, wherein the conductive portion of the nail extends from a tip of the nail by a distance comprising a distance between the n^{th} negative electrode plate and the k^{th} positive electrode plate of the electrode assembly.

4. The secondary battery penetration test apparatus as claimed in claim 1, wherein the conductive portion of the nail is in an area not comprising a tip of the nail.

5. The secondary battery penetration test apparatus as claimed in claim 1, wherein, excluding a tip of the nail, the conductive portion of the nail is in an area that is outside of a distance between the n^{th} negative electrode plate and the k^{th} positive electrode plate of the electrode assembly.

6. The secondary battery penetration test apparatus as claimed in claim 1, wherein the non-conductive portion of the nail is in an area comprising a tip of the nail.

7. The secondary battery penetration test apparatus as claimed in claim 1, wherein, excluding a tip of the nail, the non-conductive portion of the nail is in an area that is outside of a distance between the n^{th} negative electrode plate and the k^{th} positive electrode plate of the electrode assembly.

8. The secondary battery penetration test apparatus as claimed in claim 1, wherein n=k.

9. The secondary battery penetration test apparatus as claimed in claim 1, wherein n≠k.

10. The secondary battery penetration test apparatus as claimed in claim 1, wherein:
the nail comprises a conductor, and
the non-conductive portion of the nail comprises an insulating material on a surface of a nail area excluding the conductive portion.

11. The secondary battery penetration test apparatus as claimed in claim 1, wherein:
the nail comprises a non-conductor, and
the conductive portion of the nail comprises a conductive material on a surface of a nail area excluding the non-conductive portion.

12. The secondary battery penetration test apparatus as claimed in claim 1, wherein the conductive portion made of a conductor and the non-conductive portion made of a non-conductor are joined together.

13. A secondary battery penetration test method, comprising:
inserting a nail comprising a conductive portion and a non-conductive portion into an electrode assembly of a secondary battery, resulting in an inserted nail; and
positioning the nail to be seated at a position at which the conductive portion of the inserted nail short-circuits an n^{th} negative electrode plate (n is a natural number greater than or equal to 1) and a k^{th} positive electrode plate (k is a natural number greater than or equal to 1) of the electrode assembly.

14. The secondary battery penetration test method as claimed in claim 13, further comprising, charging the secondary battery prior to inserting the nail into the electrode assembly of the secondary battery.

15. The secondary battery penetration test method as claimed in claim 13, wherein n=k.

16. The secondary battery penetration test method as claimed in claim 13, wherein n≠k.

17. A nail for a secondary battery penetration test, the nail comprising:
a conductive portion inserted into an electrode assembly to short-circuit an n^{th} negative electrode plate (n is a natural number greater than or equal to 1) and a k^{th} positive electrode plate (k is a natural number greater than or equal to 1) of the electrode assembly; and
a non-conductive portion in an area of the nail excluding the conductive portion.

18. The nail as claimed in claim 17, wherein the conductive portion of the nail extends from a tip of the nail by a distance between the n^{th} negative electrode plate and the k^{th} positive electrode plate of the electrode assembly.

19. The nail as claimed in claim 17, wherein, excluding a tip of the nail, the conductive portion of the nail is in an area outside of a distance between the n^{th} negative electrode plate and the k^{th} positive electrode plate of the electrode assembly.

20. The nail as claimed in claim 17, wherein, excluding a tip of the nail, the non-conductive portion of the nail is in an area outside of a distance between the negative electrode plate and the positive electrode plate of the electrode assembly.
